(19) United States
(12) Patent Application Publication
(10) Pub. No.: US 2026/0162599 A1
(43) Pub. Date: Jun. 11, 2026

(54) DISPLAY APPARATUS AND METHOD OF OPERATING THE SAME

(71) Applicant: SAMSUNG ELECTRONICS CO., LTD., Suwon-si (KR)

(72) Inventors: Kiwoo KIM, Suwon-si (KR); Jungkweon BAE, Suwon-si (KR); Seungwon SEOK, Suwon-si (KR); Changmin KEUM, Suwon-si (KR)

(73) Assignee: SAMSUNG ELECTRONICS CO., LTD., Suwon-si (KR)

(21) Appl. No.: 19/323,648

(22) Filed: Sep. 9, 2025

Related U.S. Application Data
(63) Continuation of application No. PCT/KR2025/011326, filed on Jul. 30, 2025.

(30) Foreign Application Priority Data
Dec. 9, 2024 (KR) 10-2024-0181954

(51) Int. Cl. G09G 3/3225; H10F 39/95; H10H 29/32

(52) U.S. Cl. CPC G09G 3/3225; H10F 39/95; H10H 29/32; G09G 2300/0819; G09G 2320/0626; G09G 2354/00; G09G 2360/144; G09G 2360/145

(57) ABSTRACT

A display apparatus includes: a display panel including: light-emitting devices in a two-dimensional array; and light-sensing devices respectively corresponding to the light-emitting devices; memory storing at least one instruction; and at least one processor, wherein the at least one instruction, when executed by the at least one processor individually or collectively, causes the display apparatus to: receive a first sensing signal from the light-sensing devices during a light emission period of the light-emitting devices; receive a second sensing signal from the light-sensing devices during a non-light emission period of the light-emitting devices; and control the display panel to display an image corresponding to at least one of the first sensing signal or the second sensing signal.

### CROSS-REFERENCE TO RELATED APPLICATION

This application is a continuation of International Application No. PCT/KR2025/011326, filed on Jul. 30, 2025, which is based on and claims priority to Korean Patent Application No. 10-2024-0181954, filed on Dec. 9, 2024, in the Korean Intellectual Property Office, the disclosures of which are incorporated by reference herein in their entireties.

### BACKGROUND

### 1. Field

The disclosure relates to a display apparatus and a method of operating the same, and more particularly, to a display apparatus including light-sensing devices, and a method of operating the display apparatus.

### 2. Description of Related Art

Display apparatuses provide various functions for seamless communication with a user, such as displaying an image to provide information to the user, or sensing a user input. Recently, display apparatuses include functions for sensing biometric information of a user. Biometric information recognition methods include a capacitive method of sensing a change in capacitance formed between electrodes, an optical method of sensing incident light by using an optical sensor, and an ultrasonic method of sensing vibration by using a piezoelectric material or the like.

### SUMMARY

Provided are a display apparatus including a light-sensing device configured to sense light, and a method of operating the display apparatus.

Further, provided are a display apparatus including a light-sensing device configured to sense internal light and external light, and a method of operating the display apparatus.

Further, provided are a display apparatus in which a single light-sensing device is able to sense both internal light and external light, and a method of operating the display apparatus.

According to an aspect of the disclosure, a display apparatus may include a display panel including light-emitting devices arranged two-dimensionally, and light-sensing devices respectively corresponding to the light-emitting devices.

According to an aspect of the disclosure, a display apparatus may include: a display panel including: light-emitting devices in a two-dimensional array; and light-sensing devices respectively corresponding to the light-emitting devices; memory storing at least one instruction; and at least one processor, wherein the at least one instruction, when executed by the at least one processor individually or collectively, causes the display apparatus to: receive a first sensing signal from the light-sensing devices during a light emission period of the light-emitting devices; receive a second sensing signal from the light-sensing devices during a non-light emission period of the light-emitting devices; and control the display panel to display an image corresponding to at least one of the first sensing signal or the second sensing signal.

According to an aspect of the disclosure, a method of operating a display apparatus including a display panel that includes light-emitting devices in a two-dimensional array and light-sensing devices respectively corresponding to the light-emitting devices, may include: receiving a first sensing signal from the light-sensing devices during a light emission period of the light-emitting devices; receiving a second sensing signal from the light-sensing devices during a non-light emission period of the light-emitting devices; and controlling the display panel to display an image corresponding to at least one of the first sensing signal or the second sensing signal.

According to an aspect of the disclosure, the method of operating a display apparatus may include controlling the display panel such that an image corresponding to at least one of the first sensing signal or the second sensing signal is displayed.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view of a display apparatus according to an embodiment of the disclosure;

FIG. 2 is a cross-sectional view of a display apparatus according to an embodiment of the disclosure;

FIG. 3 is a block diagram of a display apparatus according to an embodiment of the disclosure;

FIG. 4 is a partial cross-sectional view of a display panel according to an embodiment of the disclosure;

FIG. 5 is a block diagram of a display apparatus according to an embodiment of the disclosure;

FIG. 6 is a flowchart for describing operations of a display apparatus according to an embodiment of the disclosure;

FIG. 7 is a timing diagram for describing operations of a light-emitting device and a light-sensing device when a display apparatus is in a first sensing mode;

FIG. 8 is a timing diagram for describing operations of a light-emitting device and a light-sensing device when a display apparatus is in a second sensing mode;

FIG. 9 is a flowchart for describing operations of a display apparatus according to a sensing mode, according to an embodiment of the disclosure;

FIG. 10 is a diagram illustrating a display panel in which a circuit layer, a light-sensing layer, and a light-emitting layer are sequentially arranged, according to an embodiment of the disclosure;

FIG. 11 is a diagram illustrating a display panel including a plurality of light transmission members, according to an embodiment of the disclosure;

FIG. 12 is a diagram illustrating a display panel in which a configuration of a light-emitting layer and a circuit layer serves as a light transmission member, according to an embodiment of the disclosure;

FIG. 13 is a diagram illustrating a display panel having a structure in which light emitted from a light-emitting device is directly incident on a photoelectric conversion layer, according to an embodiment of the disclosure;

FIG. 14 is a diagram illustrating a display panel in which light emitted from a light-emitting device is directly incident on a photoelectric conversion layer, according to an embodiment of the disclosure;

FIG. 15 is a diagram illustrating an example of a light-emitting layer that includes a common electrode, according to an embodiment of the disclosure;

FIG. 16 is a diagram illustrating a light-emitting layer including a light-emitting device that emits light of a plurality of wavelengths, according to an embodiment of the disclosure; and

FIG. 17 is a diagram illustrating a light-emitting layer including an organic material-based light-emitting device, according to an embodiment of the disclosure.

### DETAILED DESCRIPTION

Hereinafter, embodiments of the disclosure will be described in detail with reference to the accompanying drawings. The embodiments of the disclosure described herein are merely illustrative, and various modifications are possible from these embodiments. In the drawings, like reference numerals refer to like elements, and sizes of elements in the drawings may be exaggerated for clarity and convenience of description.

Hereinafter, an expression “on” used herein may include not only “immediately on in a contact manner” but also “on in a non-contact manner”.

Although the terms such as “first” or “second” may be used herein to describe various elements, these terms are only used to distinguish one element from another element. These terms do not define that the elements have different materials or structures from each other.

The singular expression also includes the plural meaning as long as it is not inconsistent with the context. In addition, when an element is referred to as “including” a component, the element may additionally include other components rather than excluding other components as long as there is no particular opposing recitation.

In addition, as used herein, the terms such as “ . . . er”, “ . . . unit”, “ . . . module”, etc., denote a unit that performs at least one function or operation, which may be implemented as hardware or software or a combination thereof.

The particular implementations shown and described herein are examples of the disclosure and are not intended to otherwise limit the scope of the disclosure in any way. For the sake of brevity, related-art electronics, control systems, software and other functional aspects of the systems may not be described in detail. Furthermore, line connections or connection members between elements depicted in the drawings represent functional connections and/or physical or circuit connections by way of example, and in actual applications, they may be replaced or embodied with various suitable additional functional connections, physical connections, or circuit connections.

The term “the” and other demonstratives similar thereto should be understood to include a singular form and plural forms.

The operations of a method may be performed in any suitable order unless otherwise indicated herein or otherwise clearly contradicted by context. In addition, all example terms (e.g., “such as” or “etc.”) are used for the purpose of description and are not intended to limit the scope of the disclosure unless defined by the claims.

As used herein, expressions such as “at least one of,” when preceding a list of elements, modify the entire list of elements and do not modify the individual elements of the list. For example, the expression “at least one of a, b or c” indicates only a, only b, only c, both a and b, both a and c, both b and c, or all of a, b, and c.

In the specification, spatially relative terms such as “top”, “bottom”, “upper”, “lower”, “up”, “down”, “horizontal,” “vertical”, “front”, “rear” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

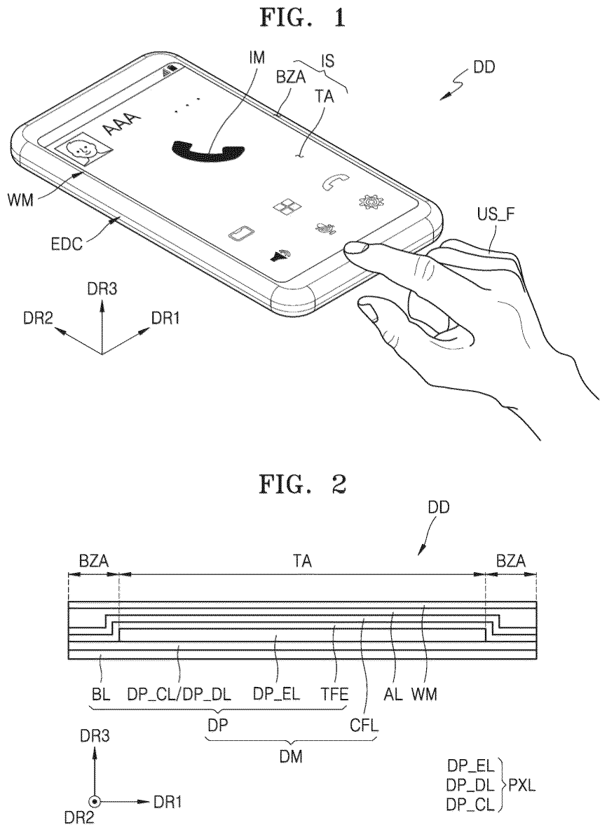

FIG. 1 is a perspective view of a display apparatus DD according to an embodiment of the disclosure. FIG. 2 is a cross-sectional view of the display apparatus DD according to an embodiment of the disclosure.

Referring to FIGS. 1 and 2, the display apparatus DD may be an apparatus that is activated in response to an electrical signal. For example, the display apparatus DD may be a mobile phone, a tablet computer, an automobile navigation system, a game console, or a wearable device, but is not limited thereto. FIG. 1 exemplarily illustrates the display apparatus DD as a mobile phone.

Furthermore, FIG. 1 exemplarily illustrates a bar-shaped, rigid-type display apparatus DD, but embodiments of the disclosure are not limited thereto. For example, the display apparatus DD may be a foldable, rollable, or slidable display apparatus DD.

An upper surface (or front surface) of the display apparatus DD may be defined as a display surface IS and may have a plane defined by a first direction DR1 and a second direction DR2. Images IM generated by the display apparatus DD may be provided to a user via the display surface IS. Hereinafter, a normal direction that is substantially perpendicular to the plane defined by the first direction DR1 and the second direction DR2 is defined as a third direction DR3. As used herein, the expression “when viewed from above the plane” may mean that it is viewed in the third direction DR3. That is, the plane may be parallel to a surface defined by the first direction DR1 and the second direction DR2.

The display surface IS may be divided into a transmissive area TA and a bezel area BZA. The transmissive area TA may be an area in which the images IM are displayed. The user visually perceives the images IM through the transmissive area TA. In the present embodiment of the disclosure, the transmissive area TA is illustrated as a quadrangular shape with rounded vertices. However, this is an illustrative example, and the transmissive area TA may have various shapes and is not limited to any particular embodiment.

The bezel area BZA is adjacent to the transmissive area TA. The bezel area BZA may have a certain color. The bezel area BZA may surround the transmissive area TA. Accordingly, the shape of the transmissive area TA may be substantially defined by the bezel area BZA. However, this is an illustrative example, and the bezel area BZA may be arranged adjacent to only one side of the transmissive area TA, or may be omitted.

The display apparatus DD may sense an external input applied from the outside. The external input may include various forms of input provided from outside the display apparatus DD. For example, the external input may include not only contact by a part of the user's body, such as the user's finger US_F, but also an external input applied when near, or at a certain distance from, the display apparatus DD (e.g., hovering). In addition, the external input may take various forms, such as a force, pressure, temperature, or light. The external input may also be provided by a separate device, such as an active pen or a digitizer pen. In addition, the display apparatus DD may sense biometric information of the user that is applied from the outside.

The exterior of the display apparatus DD may be formed by a window WM and a housing EDC. For example, the window WM and the housing EDC may be coupled to each other, and other components of the display apparatus DD, such as a display module DM, may be accommodated therein.

The front surface of the window WM defines the display surface IS of the display apparatus DD. The window WM may include an optically transparent insulating material. For example, the window WM may include glass or plastic. The window WM may have a multi-layer structure or a single-layer structure. For example, the window WM may include a plurality of plastic films coupled to each other by using an adhesive, or a glass substrate and a plastic film coupled to each other by using an adhesive.

The housing EDC may include a material having relatively high stiffness. For example, the housing EDC may include glass, plastic, or metal, or may include a plurality of frames FT and/or plates formed of a combination of these materials. The housing EDC may stably protect, from external impact, components of the display apparatus DD, which are accommodated in an internal space of the housing EDC. A battery module or the like, which supplies power necessary for the overall operation of the display apparatus DD, may be arranged between the display module DM and the housing EDC.

The display module DM may include a display panel DP and an anti-reflection layer CFL.

The display panel DP may be a component that substantially generates images. The display panel DP may be a light-emitting-type display panel DP, and for example, the display panel DP may be an organic light-emitting display panel DP, an inorganic light-emitting display panel DP, an organic-inorganic light-emitting display panel DP, a quantum dot display panel DP, a micro-light-emitting diode (LED) display panel DP, or a nano-LED display panel DP. Hereinafter, the display panel DP will be described as an organic light-emitting display panel DP.

The display panel DP includes a base layer BL, a pixel layer PXL, and an encapsulation layer TFE. The display panel DP according to the disclosure may be a flexible display panel DP. However, the disclosure is not limited thereto. For example, the display panel DP may be a foldable display panel that is foldable with respect to a folding axis, or a rigid display panel.

The base layer BL may include a synthetic resin layer. The synthetic resin layer may be a polyimide-based resin layer, and its material is not particularly limited. In addition, the base layer BL may include a glass substrate, a metal substrate, an organic/inorganic composite material substrate, or the like.

The pixel layer PXL is arranged on the base layer BL. The pixel layer PXL may include a circuit layer DP_CL, a light-sensing layer DP_DL, and a light-emitting layer DP_EL. The circuit layer DP_CL and the light-sensing layer DP_DL may be arranged on the same layer, for example, on the base layer BL. In addition, the light-emitting layer DP_EL may be arranged on the circuit layer DP_CL and the light-sensing layer DP_DL. However, the disclosure is not limited thereto. The circuit layer DP_CL, the light-sensing layer DP_DL, and the light-emitting layer DP_EL may be sequentially arranged on a surface of the base layer BL. In other words, the circuit layer DP_CL and the light-sensing layer DP_DL may be arranged on a rear surface of the light-emitting layer DP_EL.

The circuit layer DP_CL includes at least one insulating layer and a circuit device. Hereinafter, the insulating layer included in the circuit layer DP_CL will be referred to as an intermediate insulating layer. The intermediate insulating layer includes at least one intermediate inorganic film and at least one intermediate organic film. The circuit device may include a pixel circuit included in each of a plurality of pixels for displaying images, a sensor driving circuit included in each of a plurality of sensors for recognizing external information, and the like. The circuit layer DP_CL may further include signal lines connected to the pixel circuits and/or the sensor driving circuits.

For example, each of the plurality of sensors may be a fingerprint recognition sensor, a proximity sensor, an iris recognition sensor, or the like. In addition, each of the plurality of sensors may be an optical sensor configured to recognize biometric information by using an optical method. According to an embodiment of the disclosure, by using the plurality of sensors, not only biometric information such as a fingerprint but also an external input (e.g., a touch by the user) may be sensed. Thus, the display apparatus DD may not include a separate input-sensing layer for sensing an external input. In this case, the thickness of the display apparatus DD may be further reduced, and its flexibility may thereby be improved, such that the display apparatus DD may be implemented as a display apparatus DD of various types, for example, the above-described foldable-type, rollable-type, or slidable-type.

The light-emitting layer DP_EL may include light-emitting devices ED, which are included in the respective pixels and arranged in a two-dimensional array. The light-emitting device ED may be an organic material-based light-emitting device ED or an inorganic material-based light-emitting device ED. Each light-emitting device ED may include an electro-optical conversion layer 230 that emits light in response to an input electrical signal. At least one of the light-emitting devices ED may output any one of light of a first color (e.g., red), light of a second color (e.g., green), and light of a third color (e.g., blue). However, the disclosure is not limited thereto. At least one of the light-emitting devices ED may selectively output at least one of light of a first color (e.g., red), light of a second color (e.g., green), or light of a third color (e.g., blue).

The light-sensing layer DP_DL may include a light-sensing device CD included in each of the sensors. For example, the light-sensing device may be a phototransistor, but is not limited thereto. The light-sensing device CD may be a photodiode. The light-sensing device CD may include a photoelectric conversion layer OEL that generates an electrical signal in response to incident light.

The light-sensing device CD may receive at least one of internal light or external light and, in response, output an electrical signal. Here, the internal light refers to light that is emitted from the light-emitting device ED of the light-emitting layer DP_EL, travels within the display panel DP without being emitted to the outside, and is then incident on the light-sensing device CD, and the external light may refer to light that is incident on the light-sensing device CD from an external source through the display panel DP. The external light may also include light that, after being emitted from the light-emitting layer DP_EL and then to the outside of the display panel DP, is reflected by an object external to the display panel DP, for example, the user's finger, then re-enters the display panel DP, and is then incident on the light-sensing device CD. In addition, the external light may also be light that originates from an external environment, travels within the display panel DP, and is then incident on the light-sensing device CD.

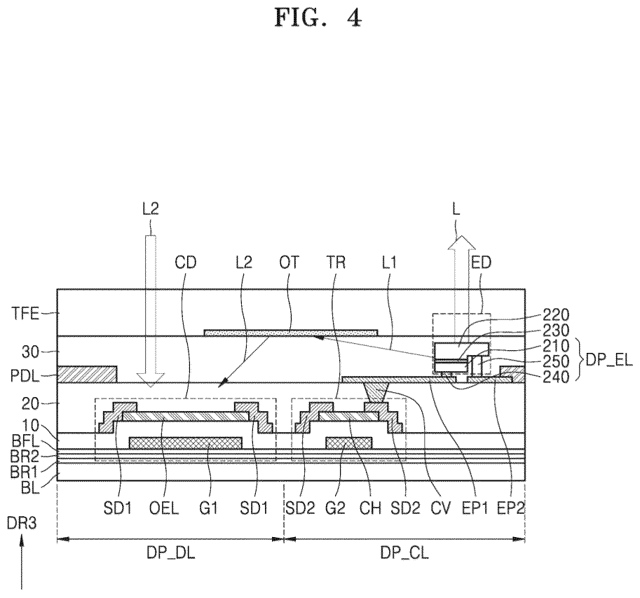

The circuit layer DP_CL, the light-sensing layer DP_DL, and the light-emitting layer DP_EL will be described in more detail below with reference to FIG. 4.

The encapsulation layer TFE seals the light-emitting layer DP_EL. The encapsulation layer TFE may include at least one organic film and at least one inorganic film. The inorganic film includes an inorganic material, and may protect the light-emitting layer DP_EL from moisture and oxygen. The inorganic film may include a silicon nitride layer, a silicon oxynitride layer, a silicon oxide layer, a titanium oxide layer, an aluminum oxide layer, or the like, but is not particularly limited thereto. The organic layer includes an organic material, and may protect the light-emitting layer DP_EL from foreign substances such as dust particles.

The anti-reflection layer CFL may be arranged on the display panel DP. The anti-reflection layer CFL may reduce the reflectance of external light incident from outside the display apparatus DD. The anti-reflection layer CFL may be formed on the display panel DP through a continuous process, but the disclosure is not limited thereto. For example, the anti-reflection layer CFL may include color filters, a black matrix, and a planarization layer. The color filters may have a certain arrangement. For example, the color filters may be arranged considering emission colors of pixels included in the display panel DP. In an embodiment of the disclosure, the anti-reflection layer CFL may include a black matrix and a reflection adjustment layer. The reflection adjustment layer may selectively absorb light in certain wavelength bands, from light reflected from inside the display panel DP and/or the display apparatus DD, or light incident from outside the display panel DP and/or the display apparatus DD. In an embodiment of the disclosure, the anti-reflection layer CFL may be a polarizing film.

According to an embodiment of the disclosure, the display apparatus DD may further include an adhesive layer AL. The window WM may be attached to the anti-reflection layer CFL by the adhesive layer AL. The adhesive layer AL may include an optically clear adhesive, an optically clear adhesive resin, or a pressure-sensitive adhesive (PSA).

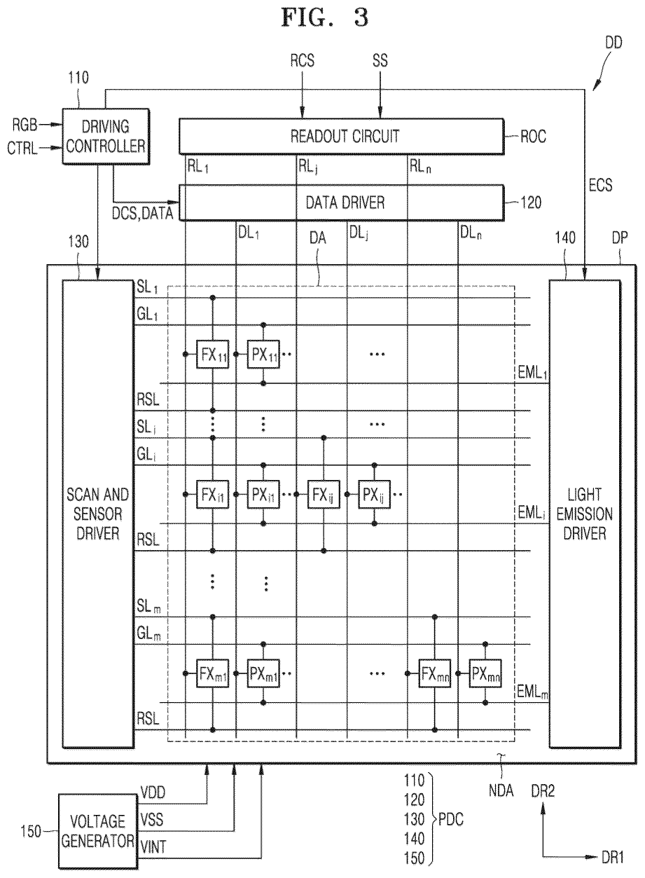

FIG. 3 is a block diagram of the display apparatus DD according to an embodiment of the disclosure.

Referring to FIG. 3, the display apparatus DD includes the display panel DP, a driving controller 110, a data driver 120, a scan and sensor driver 130, a light emission driver 140, a readout circuit ROC, and a voltage generator 150. A panel driving circuit PDC may include the driving controller 110, the data driver 120, the scan and sensor driver 130, the light emission driver 140, and the voltage generator 150.

The driving controller 110 receives an input image signal RGB and a control signal CTRL. The driving controller 110 generates an output image signal DATA by converting a data format of the input image signal RGB to be suitable for the data driver 120 and the display panel DP. The driving controller 110 outputs a scan control signal SCS, a data control signal DCS, and a light emission control signal ECS.

The data driver 120 receives the data control signal DCS and the output image signal DATA from the driving controller 110. The data driver 120 converts the output image signal DATA into data signals and outputs the data signals to a plurality of data lines DL₁ to DLₘ, which will be described below. The data signals are analog voltages that correspond to grayscale levels of the output image signal DATA.

The voltage generator 150 generates voltages necessary for an operation of the display panel DP. In the present embodiment of the disclosure, the voltage generator 150 generates a driving voltage VDD, an initialization voltage VINT, a reset voltage VRST, a sensor driving voltage VCOM, and a bias voltage VBIAS.

The display panel DP includes scan lines GL₁ to GLₙ, sensor scan lines SL₁ to SLₙ, reset lines RSL, light emission lines EML₁ to EMLₙ, data lines DL₁ to DLₘ, readout lines RL₁ to RLₖ, pixels PX, and sensors FX.

The display panel DP may include a display area DA, which corresponds to the transmissive area TA (see FIG. 1), and a non-display area NDA, which corresponds to the bezel area BZA (see FIG. 1). The pixels PX and the sensors FX may be arranged in the display area DA.

The scan and sensor driver 130 and the light emission driver 140 may be arranged in the non-display area NDA of the display panel DP.

In an embodiment of the disclosure, the scan and sensor driver 130 is arranged adjacent to a first side of the display area DA within the display panel DP. The scan and sensor driver 130 receives the scan control signal SCS from the driving controller 110. In response to the scan control signal SCS, the scan and sensor driver 130 may output scan signals to the scan lines GL₁ to GLₙ and output a reset signal to the reset lines RSL. Each of the scan lines GL₁ to GLₙ, and the reset lines RSL extend from the scan and sensor driver 130 in the first direction DR1.

The light emission driver 140 is arranged adjacent to a second side of the display area DA within the display panel DP. The light emission driver 140 receives the light emission control signal ECS from the driving controller 110. In response to the light emission control signal ECS, the light emission driver 140 may output light emission signals to the light emission lines EML₁ to EMLₙ. The light emission lines EML₁ to EMLₙ extend from the light emission driver 140 in a direction opposite to the first direction DR1.

The scan lines GL₁ to GLₙ, the reset lines RSL, and the light emission lines EML₁ to EMLₙ are arranged spaced apart from each other in the second direction DR2. The data lines DL₁ to DLₘ extend from the data driver 120 in a direction opposite to the second direction DR2, and are arranged spaced apart from each other in the first direction DR1.

The plurality of pixels PX are electrically connected to the scan lines GL₁ to GLₙ, the light emission lines EML₁ to EMLₙ, and the data lines DL₁ to DLₘ, respectively. For example, as illustrated in FIG. 3, pixels in the first row may be connected to the scan line GL₁ and the light emission line EML₁. In addition, pixels in the second row may be connected to the scan line GL₂ and the light emission line EML₂.

Each of the plurality of pixels PX includes the light-emitting device ED and a pixel circuit configured to control light emission of the light-emitting device ED. The light-emitting device ED is arranged in the light-emitting layer DP_EL, and the pixel circuit may be arranged in the circuit layer DP_CL. The pixel circuit may include one or more transistors and one or more capacitors. The scan and sensor driver 130 and the light emission driver 140 may include transistors formed via the same process as that for the pixel circuit.

Each of the plurality of pixels PX may receive the driving voltage VDD and the initialization voltage VINT from the voltage generator 150.

Each of the sensors FX may include the light-sensing device CD and a sensor driving circuit. The sensor driving circuit may be formed via the same process as that for the pixel circuit. That is, the sensor driving circuit and the pixel circuit may be formed within the circuit layer DP_CL. Moreover, the light-sensing device CD may also be formed via the same process as that for the pixel circuit.

Each of the sensors FX may be connected to a corresponding one of the scan lines GL₁ to GLₙ and to a corresponding one of the readout lines RL₁ to RLₖ. The sensors FX may be connected in common to the reset lines RSL. In the present embodiment of the disclosure, the number of sensors FX may be equal to the number of pixels PX, but is not limited thereto. In an embodiment of the disclosure, the number of sensors FX arranged in the display panel DP may be greater than or less than the number of pixels PX.

The readout circuit ROC receives a readout control signal RCS. In response to the readout control signal RCS, the readout circuit ROC may receive a sensing signal from the readout lines RL₁ to RLₖ, and output a readout signal SS corresponding to the sensing signal. Hereinafter, for convenience of descriptions, the readout signal SS that corresponds to the sensing signal may also be simply referred to as a sensing signal.

FIG. 3 illustrates that the readout circuit ROC receives the readout control signal RCS from an external source (e.g., an application processor, a graphics controller, or a main processor) and outputs the readout signal SS to the outside, but the disclosure is not limited thereto. In an embodiment of the disclosure, the readout circuit ROC may receive the readout control signal RCS from the driving controller 110 and output the readout signal SS to the driving controller 110.

In an embodiment of the disclosure, the sensors FX and the readout circuit ROC may operate in a screen check mode, a blood pressure sensing mode, a fingerprint sensing mode, a touch sensing mode, and the like. During the screen check mode, the readout signal SS output from the readout circuit ROC may include information about a light emission state of the light-emitting devices ED. During the blood pressure sensing mode, the readout signal SS output from the readout circuit ROC may include information about the user's blood pressure. During the fingerprint sensing mode, the readout signal SS output from the readout circuit ROC may include information about the user's fingerprint. During the touch sensing mode, the readout signal SS output from the readout circuit ROC may include information about the user's touch position. Information about a light emission state of the light-emitting devices ED may be obtained via internal light, and information about the user's blood pressure, information about the user's fingerprint, and information about the user's touch position may be obtained via external light.

In the example illustrated in FIG. 3, the scan and sensor driver 130 is arranged to face the light emission driver 140 with the pixels PX therebetween, but the disclosure is not limited thereto. For example, the scan and sensor driver 130 and the light emission driver 140 may be arranged side-by-side at positions adjacent to the first side or the second side of the display area DA within the display panel DP. In an embodiment of the disclosure, the scan and sensor driver 130 and the light emission driver 140 may be configured as a single circuit.

The sensor FXᵢⱼ may be electrically connected to the sensor scan line SLⱼ, the reset line RSL, and the readout line RLⱼ. The sensor FXᵢⱼ includes the light-sensing device CD and a sensor driving circuit. The light-sensing device CD may be a phototransistor that includes the photoelectric conversion layer OEL. The sensor driving circuit may include one or more transistors. For example, the sensor driving circuit may include a reset transistor, an amplification transistor, an output transistor, and the like. The sensor driving circuit may, in response to a reset signal RST, reset the light-sensing device CD, amplify a signal output from the light-sensing device CD, and then, in response to a sensor scan signal SLᵢ, transmit a sensing signal FSⱼ to the readout line RLⱼ.

FIG. 4 is a partial cross-sectional view of the display panel DP according to an embodiment of the disclosure.

Transistors are arranged in the circuit layer DP_CL, the light-sensing devices CD are arranged in the light-sensing layer DP_DL, and the light-emitting devices ED are arranged in the light-emitting layer DP_EL. For convenience of descriptions, FIG. 4 illustrates one transistor in the circuit layer DP_CL, one light-sensing device CD in the light-sensing layer DP_DL, and one light-emitting device ED in the light-emitting layer DP_EL.

The display panel DP may include the base layer BL, and the circuit layer DP_CL, the light-sensing layer DP_DL, the light-emitting layer DP_EL, and the encapsulation layer TFE that are arranged on the base layer BL. The circuit layer DP_CL and the light-sensing layer DP_DL may be arranged on the same layer, for example, on the base layer BL. In other words, the circuit layer DP_CL and the light-sensing layer DP_DL may be arranged on a rear surface of the light-emitting layer DP_EL. In addition, the light-emitting layer DP_EL may be arranged on the circuit layer DP_CL and the light-sensing layer DP_DL, and the encapsulation layer TFE may be arranged on the light-emitting layer DP_EL.

The base layer BL may include a synthetic resin layer. The synthetic resin layer may include a thermosetting resin. In particular, the synthetic resin layer may be a polyimide-based resin layer, and its material is not particularly limited. The synthetic resin layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. In addition, the base layer BL may include a glass substrate, a metal substrate, an organic/inorganic composite material substrate, or the like.

At least one inorganic layer is formed on an upper (or front) surface of the base layer BL. The inorganic layer may include at least one of aluminum oxide, titanium oxide, silicon oxide, silicon oxynitride, zirconium oxide, or hafnium oxide. The inorganic layer may be formed in multiple layers. The multiple inorganic layers may constitute barrier layers BR1 and BR2 and/or a buffer layer BFL, which will be described below. The barrier layers BR1 and BR2 and the buffer layer BFL may be selectively arranged.

The barrier layers BR1 and BR2 prevent the entry of foreign substances from the outside. The barrier layers BR1 and BR2 may each include a silicon oxide layer and a silicon nitride layer. A plurality of silicon oxide layers and silicon nitride layers may be provided, and these silicon oxide layers and silicon nitride layers may be alternately stacked.

The buffer layer BFL may be arranged on the barrier layers BR1 and BR2. The buffer layer BFL improves the adhesion between the base layer BL and a semiconductor pattern and/or a conductive pattern. The buffer layer BFL may include a silicon oxide layer and a silicon nitride layer. The silicon oxide layer and the silicon nitride layer may be alternately stacked.

The barrier layers BR1 and BR2 and the buffer layer BFL may be continuously arranged on lower surfaces of the light-sensing layer DP_DL and the circuit layer DP_CL.

The light-sensing device CD may be arranged in the light-sensing layer DP_DL. The light-sensing device CD may be of a phototransistor type or a photodiode type. For example, the light-sensing device CD may include a gate electrode G1, a photoelectric conversion layer OEL, and two first source/drain electrodes SD1.

The circuit layer DP_CL may include a driving transistor that drives the light-emitting device ED. A driving transistor TR may include a gate electrode G2, a channel layer CH, and two second source/drain electrodes SD2. However, the disclosure is not limited thereto, and the circuit layer DP_CL may include multiple transistors for screen compensation.

For example, the gate electrode G1 of the light-sensing device CD and the gate electrode G2 of the driving transistor TR may be arranged on the buffer layer BFL. The gate electrode G1 of the light-sensing device CD and the gate electrode G2 of the driving transistor TR may be arranged spaced apart from each other on the same layer, for example, on the buffer layer BFL.

The gate electrode G1 of the light-sensing device CD and the gate electrode G2 of the driving transistor TR may include titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), or the like, but are not particularly limited thereto.

A first insulating layer 10 may be arranged on the buffer layer BFL. The first insulating layer 10 may be arranged to extend over the light-sensing layer DP_DL and the circuit layer DP_CL, and may cover the gate electrode G1 of the light-sensing device CD and the gate electrode G2 of the driving transistor TR. The first insulating layer 10 may serve as a gate insulating layer for the gate electrode G1 of the light-sensing device CD and the gate electrode G2 of the driving transistor TR.

The first insulating layer 10 may be an inorganic layer and/or an organic layer, and may have a single-layer or a multi-layer structure. The first insulating layer 10 may include at least one of aluminum oxide, titanium oxide, silicon oxide, silicon nitride, silicon oxynitride, zirconium oxide, or hafnium oxide. In the present embodiment of the disclosure, the first insulating layer 10 may be a single silicon oxide layer.

The photoelectric conversion layer OEL of the light-sensing device CD and the channel layer CH of the driving transistor TR may be arranged on the first insulating layer 10. The photoelectric conversion layer OEL of the light-sensing device CD and the channel layer CH of the driving transistor TR may be arranged spaced apart from each other on the same layer, that is, on the first insulating layer 10. The photoelectric conversion layer OEL of the light-sensing device CD and the channel layer CH of the driving transistor TR may include semiconductor material (e.g., the same semiconductor material). The semiconductor material may include a silicon semiconductor. For example, the silicon semiconductor may include amorphous silicon, polycrystalline silicon, or the like. Alternatively, the semiconductor material may include an oxide of a material selected from among Group 12, 13, and 14 metals such as indium (In), gallium (Ga), tin (Sn), cadmium (Cd), aluminum (Al), germanium (Ge), zinc, or hafnium (Hf), and combinations thereof. However, the disclosure is not limited thereto, and the photoelectric conversion layer OEL of the light-sensing device CD and the channel layer CH of the driving transistor TR may also include perovskite, quantum dots (QDs), or the like.

Two first source/drain electrodes SD1 may be arranged spaced apart from each other on the photoelectric conversion layer OEL of the light-sensing device CD, and two second source/drain electrodes SD2 may be arranged spaced apart from each other on the channel layer CH of the driving transistor TR. The first source/drain electrodes SD1 and the second source/drain electrodes SD2 may each be formed of a conductive material. The first source/drain electrodes SD1 and the second source/drain electrodes SD2 may be formed of the same material as the gate electrodes G1 and G2, or may be formed of a different material.

As described above, the light-sensing device CD of the light-sensing layer DP_DL and the transistor of the circuit layer DP_CL may be formed on the same layer via the same process, and thus, process efficiency and cost may be reduced.

A second insulating layer 20 may be arranged on the light-sensing device CD and the driving transistor TR. The second insulating layer 20 may be an inorganic layer or an organic layer. The organic layer may include, but is not particularly limited to, benzocyclobutene (BCB), polyimide, hexamethyldisiloxane (HMDSO), general-purpose polymers such as polymethyl methacrylate (PMMA) or polystyrene (PS), polymer derivatives having phenolic groups, acrylic-based polymers, imide-based polymers, aryl ether-based polymers, amide-based polymers, fluorine-based polymers, p-xylene-based polymers, vinyl alcohol-based polymers, blends thereof, and the like.

The light-emitting layer DP_EL may be arranged on the light-sensing layer DP_DL and the circuit layer DP_CL. The light-emitting layer DP_EL may include the light-emitting device ED, a pixel defining layer PDL, and a third insulating layer 30.

The light-emitting device ED may be an inorganic material-based light-emitting device ED. However, the disclosure is not limited thereto, and the light-emitting device ED may also be an organic material-based light-emitting device. For example, the light-emitting device ED may include a first-type semiconductor layer 210, a second-type semiconductor layer 220, the electro-optical conversion layer 230 arranged between the first-type semiconductor layer 210 and the second-type semiconductor layer 220, a first electrode 240 electrically connected to the first-type semiconductor layer 210, and a second electrode 250 electrically connected to the second-type semiconductor layer 220.

The first electrode 240 and the second electrode 250 of the light-emitting device ED may be arranged to be oriented in the same direction. Both the first electrode 240 and the second electrode 250 may be arranged below the electro-optical conversion layer 230. Accordingly, the first electrode 240 and the second electrode 250 of the light-emitting device ED may be respectively directly connected to a first electrode pad EP1 and a second electrode pad EP2, which are arranged on the circuit layer DP_CL.

In some embodiments, the first-type semiconductor layer 210 may include a p-type semiconductor layer. The p-type semiconductor layer may be selected from semiconductor materials having a composition formula of InₓAl_{y}Ga_{1-x-y}N (where 0≤x≤1, 0≤y≤1, and 0≤x+y≤1), for example, GaN, AlN, AlGaN, InGaN, InN, InAlGaN, or AllnN, and may be doped with a p-type dopant such as Mg, Zn, Ca, Sr, or Ba.

The second-type semiconductor layer 220 may include, for example, an n-type semiconductor layer. The n-type semiconductor layer may be selected from semiconductor materials having a composition formula of InₓAl_{y}Ga_{1-x-y}N (where 0≤x≤1, 0≤y≤1, and 0≤x+y≤1), for example, GaN, AlN, AlGaN, InGaN, InN, InAlGaN, or AllnN, and may be doped with an n-type dopant such as Si, Ge, or Sn.

The electro-optical conversion layer 230 is a region where electrons and holes recombine, and as electrons and holes recombine, they transition to a lower energy level and may generate light having a corresponding wavelength. For example, the electro-optical conversion layer 230 may be formed including a semiconductor material having a composition formula of InₓAl_{y}Ga_{1-x-y}N (where 0≤x≤1, 0≤y≤1, and 0≤x+y≤1), and may be formed as a single quantum well structure or a multi-quantum well (MQW) structure. In addition, the electro-optical conversion layer 230 may also include a quantum wire structure or a quantum dot structure.

In a case in which the electro-optical conversion layer 230 includes indium (In), the electro-optical conversion layer 230 may emit light of a shorter wavelength as its indium content decreases. For example, in a case in which the electro-optical conversion layer 230 includes InGaN or AlInGaN, when the indium content in the nitride semiconductor material is about 35 at %, the electro-optical conversion layer 230 emits red light of about 630 nm, when the indium content is about 30 at %, the electro-optical conversion layer 230 emits yellow light of about 560 nm; and when the indium content is about 25 at %, the electro-optical conversion layer 230 may emit green light of about 520 nm. In addition, when the indium content is about 15 at %, the electro-optical conversion layer 230 may emit blue light of about 450 nm. For example, the electro-optical conversion layer 230 of a first light-emitting element ED1 may include an indium content of about 35 at %, and may emit red light.

FIG. 4 illustrates that the first-type semiconductor layer 210 includes a p-type semiconductor layer and the second-type semiconductor layer 220 includes an n-type semiconductor layer, but the disclosure is not limited thereto. In an embodiment of the disclosure, the first-type semiconductor layer 210 may include an n-type semiconductor layer, and the second-type semiconductor layer 220 may include a p-type semiconductor layer.

The pixel defining layer PDL may form an opening that groups the light-emitting device ED and the light-sensing device CD that correspond to each other. The photoelectric conversion layer OEL of the light-sensing device CD and the electro-optical conversion layer 230 of the light-emitting device ED may be arranged within the opening. In an embodiment of the disclosure, the pixel defining layer PDL may further include a black material. The pixel defining layer PDL may further include a black organic dye/pigment, such as carbon black or aniline black. The pixel defining layer PDL may be formed by mixing a blue organic material and a black organic material. The pixel defining layer PDL may further include a liquid-repellent organic material.

The third insulating layer 30 may cover the light-emitting device ED and the pixel defining layer PDL, and may have a flat upper surface (or front surface). The third insulating layer 30 may include at least one of organic materials such as organic silicon oxide (SiO_{X}) (e.g., polyethylene terephthalate, polyethylene naphthalate, polycarbonate, polyimide, polyethylene sulfonate, polyoxymethylene, polyarylate, or hexamethyldisiloxane), silicon nitride (SiN_{X}), or silicon oxynitride (SiO_{X}N_{Y}).

A light transmission member OT, which transmits, to the light-sensing device CD, light emitted from the light-emitting device ED, may be arranged on the light-emitting layer DP_EL. The light transmission member OT may have a shape that extends between the light-emitting device ED and the light-sensing device CD in a direction parallel to a surface of the light-emitting layer DP_EL (in other words, a direction perpendicular to the thickness direction (D3) of the display panel DP).

The photoelectric conversion layer OEL of the light-sensing device CD may include an area that does not overlap the light transmission member OT in the thickness direction of the display panel DP. External light may be easily incident through the area of the photoelectric conversion layer OEL of the light-sensing device CD that does not overlap the light transmission member OT. The light transmission member OT may include at least one of a waveguide or a reflection plate.

Although it has been described that the light transmission member OT is arranged on the light-emitting layer DP_EL, the disclosure is not limited thereto. The light transmission member OT may be arranged within the light-emitting layer DP_EL. For example, the light transmission member OT may be arranged such that its lower surface is higher than the upper surface (front surface) of the light-emitting layer DP_EL relative to the lower surface of the light-emitting layer DP_EL, allowing light emitted from the light-emitting layer DP_EL to be transmitted to the light-sensing device CD.

Although it has been described that the photoelectric conversion layer OEL of the light-sensing device CD includes an area that does not overlap the light transmission member OT in the thickness direction of the display panel DP, the disclosure is not limited thereto. In a case in which the light transmission member OT is a transparent waveguide, the light transmission member OT may transmit externally incident light. The entire photoelectric conversion layer OEL of the light-sensing device CD may overlap the light transmission member OT in the thickness direction of the display panel DP.

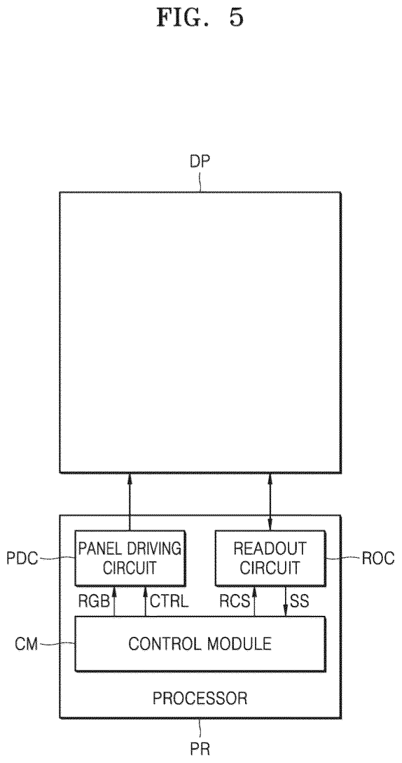

FIG. 5 is a block diagram of the display apparatus DD according to an embodiment of the disclosure.

The display apparatus DD may include the display panel DP, the panel driving circuit PDC, the readout circuit ROC, and a control module CM. The panel driving circuit PDC may include the driving controller 110, the data driver 120, the scan and sensor driver 130, the light emission driver 140, and the voltage generator 150, which are illustrated in FIG. 3.

The control module CM may control the panel driving circuit PDC such that an image is displayed on the display panel DP. The control module CM provides an input image signal RGB and a control signal CTRL to the panel driving circuit PDC.

The control module CM may control the readout circuit ROC in correspondence with a mode of the display panel DP. The control module CM may provide a readout control signal RCS to the readout circuit ROC, and receive a readout signal SS from the readout circuit ROC. The panel driving circuit PDC, the readout circuit ROC, and the control module CM are collectively referred to as a processor PR.

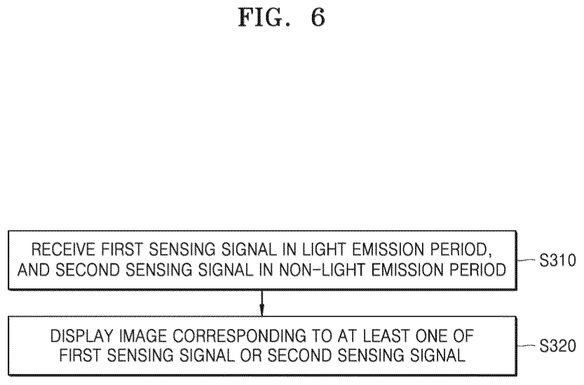

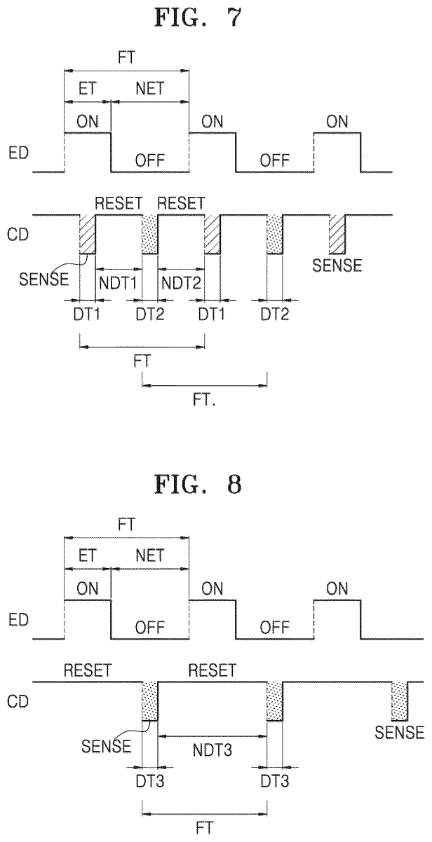

FIG. 6 is a flowchart for describing operations of the display apparatus DD according to an embodiment of the disclosure, FIG. 7 is a timing diagram for describing operations of the light-emitting device ED and the light-sensing device CD when the display apparatus DD is in a first sensing mode, and FIG. 8 is a timing diagram for describing operations of the light-emitting device ED and the light-sensing device CD when the display apparatus DD is in a second sensing mode.

Referring to FIG. 6, the processor PR may receive, from the display panel DP, a first sensing signal resulting from sensing by the light-sensing device CD during a light emission period ET of the light-emitting device ED, and a second sensing signal resulting from sensing by the light-sensing device CD during a non-light emission period NET of the light-emitting device ED (S310).

As illustrated in FIGS. 7 and 8, each light-emitting device ED may, on a per-frame (FT) basis, emit light during the light emission period ET and may not emit light during the non-light emission period NET. Based on a scan signal GL, a data signal DL, and a light emission control signal EML, the light-emitting device ED may alternately perform an operation of emitting light during the light emission period ET and an operation of not emitting light during the non-light emission period NET. For example, when the scan signal GL, the data signal DL, and the light emission control signal EML are all ON, the light-emitting device ED emits light, and the time period during which light is emitted may be referred to as the light emission period ET. When the scan signal GL and the data signal DL are ON but the light emission control signal EML is OFF, the light-emitting device ED does not emit light, and the time period during which light is not emitted may be referred to as the non-light emission period NET.

The time period of each light-sensing device CD may be divided into sensing periods DT1, DT2, and DT3 and non-sensing periods NDT1, NDT2, and NDT3. Based on a sensor scan signal SL, a readout signal RL, and a reset signal RSL, the time period of the light-sensing device CD may be divided into the sensing periods DT1, DT2, and DT3, during which light is sensed, and the non-sensing periods NDT1, NDT2, and NDT3, during which light is not sensed. For example, when the scan signal GL is ON, the light-sensing device CD may sense light, and when the readout signal RL is ON, a sensing signal resulting from the sensing may be output to the readout circuit. The time period during which light is sensed may be referred to as a sensing period (e.g., DT1, DT2, or DT3). When a scan signal is OFF after a reset signal is input, the light-sensing device CD does not sense light, and the time period during which light is not sensed may be referred to as a non-sensing period (e.g., NDT1, NDT2, or NDT3).

According to a sensing mode, the light-sensing device CD may operate based on different sensing periods DT1, DT2, and DT3 and non-sensing periods NDT1, NDT2, and NDT3.

As illustrated in FIG. 7, in a first sensing mode, the light-sensing device CD may sense light during each of the light emission period ET and the non-light emission period NET of the light-emitting device ED. For example, in the first sensing mode, the sensing periods DT1 and DT2 may include a first sensing period DT1 included in the light emission period ET, and a second sensing period DT2 included in the non-light emission period NET. Each of the first sensing period DT1 and the second sensing period DT2 may be shorter than the light emission period ET and the non-light emission period NET, respectively. A signal resulting from sensing during the first sensing period DT1, i.e., the light emission period ET, may be referred to as a first sensing signal, and a signal resulting from sensing during the second sensing period DT2, i.e., the non-light emission period NET, may be referred to as a second sensing signal.

The first sensing signal is a result of sensing during the light emission period ET, and thus may include information about internal light, which is light that is emitted from the light-emitting device ED and then incident on the light-sensing device CD through the display panel DP without traveling toward the outside of the display panel DP, and external light, which is light incident on the light-sensing device CD from an external source through the display panel DP.

The second sensing signal is a result of sensing during the non-light emission period NET, and thus may include information about external light, which is light incident on the light-sensing device CD from an external source through the display panel DP. The external light may include light that is emitted from the display panel DP, is then reflected by an object outside the display panel DP (e.g., the user's finger), and then re-enters the display panel DP.

In the first sensing mode, the light-sensing device CD may repeatedly operate on a per-frame (FT) basis based on the first sensing period DT1, a first non-sensing period NDT1, the second sensing period DT2, and a second non-sensing period NDT2. The period between occurrences of the first sensing period DT1 may be equal to the period of the frame FT, and the period between occurrences of the second sensing period DT2 may be equal to the period of the frame FT. The interval between the first sensing period DT1 and the second sensing period DT2, i.e., the first non-sensing period NDT1, or the interval between the second sensing period DT2 and the subsequent first sensing period DT1, i.e., the second non-sensing period NDT2, may be longer than the first sensing period DT1 and the second sensing period DT2. By increasing the interval between the first sensing period DT1 and the second sensing period DT2, noise generation may be reduced.

In a second sensing mode, the light-sensing device CD may repeatedly operate on a per-frame (FT) basis based on a third sensing period DT3 and a third non-sensing period NDT3. The period between occurrences of the third sensing period DT3 may be equal to the period of the frame FT. The third sensing period DT3 may have the same duration as the second sensing period DT2. However, the disclosure is not limited thereto. The duration of the third sensing period DT3 may be longer than or equal to that of the second sensing period DT2.

A signal resulting from sensing during the third sensing period DT3, i.e., the non-light emission period NET, may be referred to as a second sensing signal. The second sensing signal is a result of sensing during the non-light emission period NET, and thus may include information about external light, which is light incident on the light-sensing device CD from an external source through the display panel DP. The external light may include light that is emitted from the display panel DP, is then reflected by an object outside the display panel DP (e.g., the user's finger), and then re-enters the display panel DP.

The processor PR may control the display panel DP such that an image corresponding to at least one of the first sensing signal or the second sensing signal is displayed (S320). The processor PR may vary the method of displaying an image according to the sensing mode of the display apparatus.

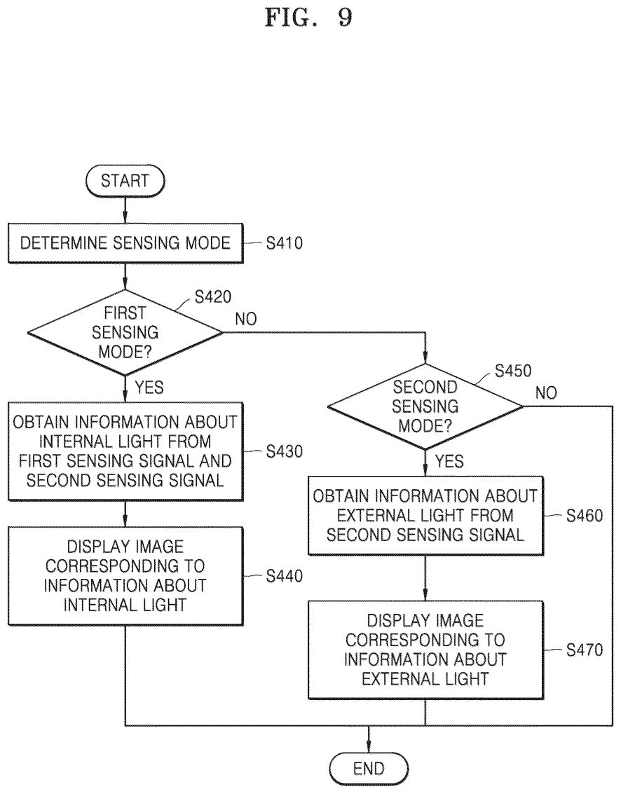

FIG. 9 is a flowchart for describing operations of a display apparatus according to a sensing mode, according to an embodiment of the disclosure.

Referring to FIG. 9, the display apparatus may determine a sensing mode of the display apparatus (S410). For example, the display apparatus may operate in a first sensing mode for a certain time period after it is reset, or may operate in the first sensing mode periodically for a certain time period. In addition, the display apparatus may operate in a second sensing mode for time periods other than when it operates in the first sensing mode. The second sensing mode may vary depending on an application of the display apparatus. For example, the second sensing mode may be classified into a blood pressure sensing mode, a fingerprint sensing mode, a touch mode, and the like.

When the sensing mode of the display apparatus is the first sensing mode, the processor PR may control the display panel DP such that light sensors operate in the first sensing mode. Each light-emitting device ED in the display panel DP may operate while repeatedly alternating between the light emission period ET and the non-light emission period NET on a per-frame (FT) basis, and the processor PR may receive a first sensing signal resulting from sensing by the light-sensing device CD during the light emission period ET of the light-emitting device ED, and a second sensing signal resulting from sensing by the light-sensing device CD during the non-light emission period NET of the light-emitting device ED.

When it is determined that the sensing mode of the display apparatus is the first sensing mode, (‘YES’ in S420), the processor PR may obtain information about internal light by using the first sensing signal and the second sensing signal (S430). The first sensing signal is a result of sensing during the light emission period ET of the pixels, and thus may include information about internal light and information about external light. The second sensing signal is a result of sensing during the non-light emission period NET of the pixels, and thus may include only information about external light. The processor PR may obtain information about internal light from a difference between the first sensing signal and the second sensing signal. The internal light corresponds to information about light emitted from the light-emitting device ED, and thus, the information about the internal light may include information about the light emission state of the light-emitting device ED. When the functionality of the light-emitting device ED has deteriorated, the internal light may have an intensity that is less than or equal to a reference value.

In response to the information about the internal light, the processor PR may control the display panel DP such that the luminance of an image is adjusted (S440). A light emission control signal of greater intensity may be provided to the light-emitting device ED whose light emission intensity is less than or equal to a reference value. Thus, by increasing the intensity of light emitted from the light-emitting device ED, a luminance deviation of an image displayed on the display panel DP may be reduced.

When the sensing mode of the display apparatus is the second sensing mode, the processor PR may control the display panel DP such that the light-sensing devices CD operate in the second sensing mode. The light-emitting device ED in the display panel DP may repeatedly operate based on the light emission period ET and the non-light emission period NET on a per-frame (FT) basis, and the processor PR may receive, from the display panel DP, a second sensing signal resulting from sensing by the light-sensing device CD during the non-light emission period NET of the light-emitting device ED.

When it is determined that the sensing mode of the display apparatus is the second sensing mode (‘YES’ in S450), the processor PR may obtain information about external light by using the second sensing signal (S460).

The processor PR may control the display panel DP such that an image corresponding to the external light is displayed (S470). The method of displaying an image corresponding to external light may vary depending on the type of the second sensing mode.

For example, when the second sensing mode is a fingerprint sensing mode, the external light may include light that is emitted from the light-emitting device ED, is then reflected by the user's fingerprint, and is then incident on the light-sensing device CD through the display panel DP. Information about the external light may include information about the user's fingerprint. The processor PR may obtain fingerprint information by using the information about the external light, and perform an authentication process of comparing the obtained fingerprint information with prestored fingerprint information. The processor PR may control the display panel DP such that an image including a result of the fingerprint authentication is displayed on the display panel DP.

The method, performed by the processor PR, of displaying an image corresponding to external light when the second sensing mode is the fingerprint sensing mode has been described, but the disclosure is not limited thereto. The second sensing mode may be a biometric sensing mode, a blood pressure sensing mode, a touch sensing mode, an illuminance sensing mode, or the like, and the second sensing signal may correspond to external light including information about a biometric signal, information about blood pressure, information about whether a touch has occurred, or information about the illuminance of an external environment. The processor PR may control the display panel DP such that an image corresponding to that result is displayed.

In a case in which a light-sensing device for sensing internal light and a light-sensing device for sensing external light are provided separately, the resolution of the display apparatus may be impaired by the arrangement of these light-sensing devices. The display apparatus according to an embodiment of the disclosure may achieve high resolution because a single light-sensing device may sense both internal light and external light.

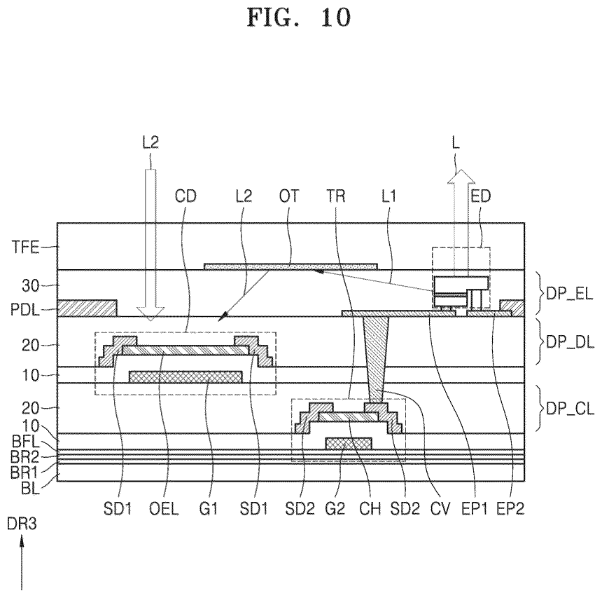

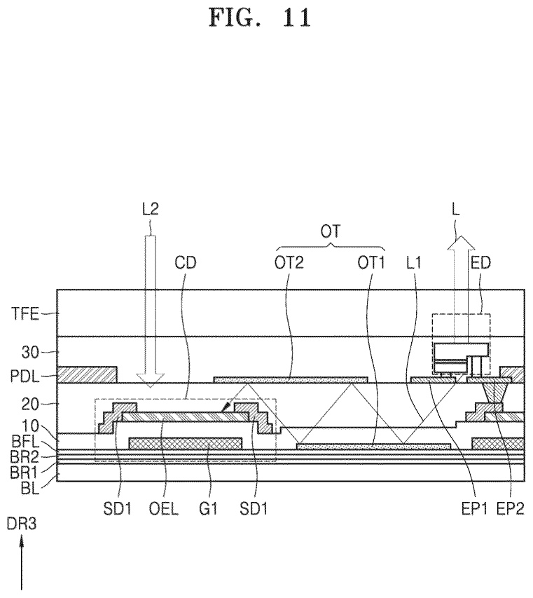

FIG. 10 is a diagram illustrating a display panel in which the circuit layer DP_CL, the light-sensing layer DP_DL, and the light-emitting layer DP_EL are sequentially arranged, according to an embodiment of the disclosure. Comparing FIGS. 4 and 10, the light-sensing layer DP_DL may be arranged between the circuit layer DP_CL and the light-emitting layer DP_EL. By arranging the light-sensing layer DP_DL between the circuit layer DP_CL and the light-emitting layer DP_EL, a larger area for the circuit layer DP_CL may be obtained.

FIG. 11 is a diagram illustrating the display panel DP including a plurality of light transmission members OT, according to an embodiment of the disclosure. Comparing FIG. 4 and FIG. 11, the light transmission member OT may include a first light transmission member OT1 and a second light transmission member OT2, which are arranged spaced apart from each other with the photoelectric conversion layer OEL therebetween in the thickness direction of the display panel DP. For example, the light transmission members OT may be arranged between the light-sensing device CD and the light-emitting device ED, which correspond to each other, in a direction perpendicular to the thickness direction of the display panel DP. The first light transmission member OT1 is arranged below the light-emitting device ED and the photoelectric conversion layer OEL, and the second light transmission member OT2 may be arranged above the photoelectric conversion layer OEL.

Light emitted from the light-emitting device ED, after being reflected at least once by the first light transmission member OT1 and the second light transmission member OT2, may be incident on the photoelectric conversion layer OEL. Because the light transmission member OT of FIG. 11 uses light emitted from a rear surface of the light-emitting device ED, the utilization of light emitted from the light-emitting device ED may be increased.

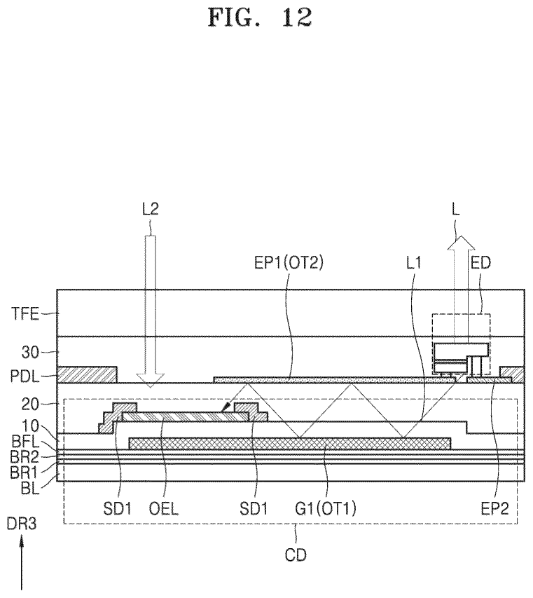

FIG. 12 is a diagram illustrating a display panel in which a configuration of a light-emitting layer and a circuit layer serves as a light transmission member, according to an embodiment of the disclosure. Referring to FIG. 12, the first electrode 240 of the light-emitting device ED may serve as the second light transmission member OT2, and the gate electrode G1 of the light-sensing device CD may serve as the first light transmission member OT1.

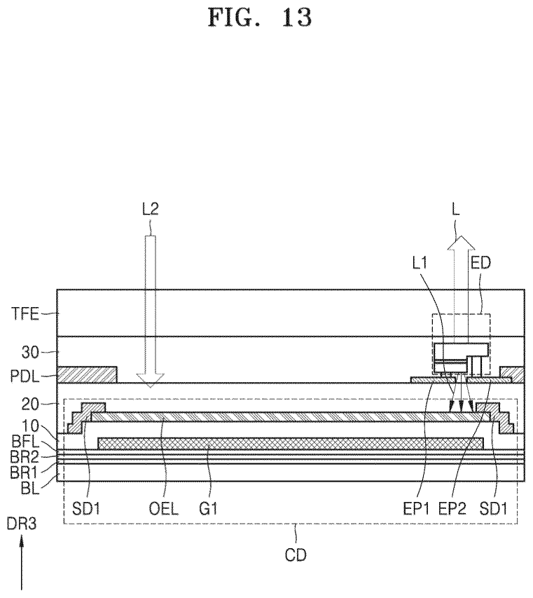

FIG. 13 is a diagram illustrating a display panel having a structure in which light emitted from a light-emitting device is directly incident on a photoelectric conversion layer, according to an embodiment of the disclosure. In the thickness direction of the display panel DP, a partial area of the photoelectric conversion layer OEL may overlap the light-emitting device ED, and another partial area of the photoelectric conversion layer OEL may not overlap the light-emitting device ED. Because the photoelectric conversion layer OEL directly senses light emitted from the light-emitting device ED, light sensing efficiency may be increased.

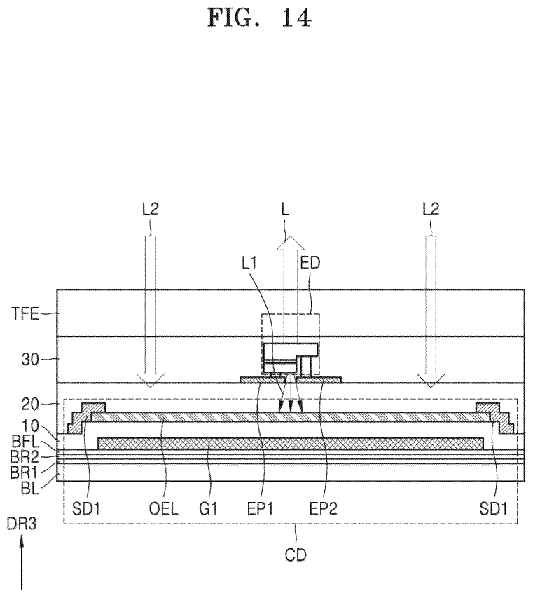

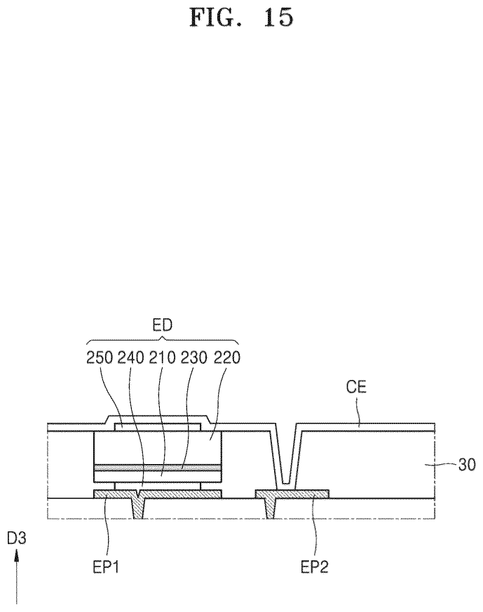

FIG. 14 is a diagram illustrating a display panel in which light emitted from a light-emitting device is directly incident on the photoelectric conversion layer OEL, according to an embodiment of the disclosure. In the thickness direction of the display panel DP, a center region of the photoelectric conversion layer OEL may overlap the light-emitting device ED, and two edge regions of the photoelectric conversion layer OEL may not overlap the light-emitting device ED. As the area of the photoelectric conversion layer OEL onto which external light is incident increases, the sensing efficiency for external light may be increased.

The light-emitting device applied to a display apparatus according to an embodiment of the disclosure may have various forms.

FIG. 15 is a diagram illustrating an example of a light-emitting layer that includes a common electrode, according to an embodiment of the disclosure.

Referring to FIG. 15, the light-emitting device ED may be an inorganic material-based light-emitting device. For example, the light-emitting device ED may include the first-type semiconductor layer 210, the second-type semiconductor layer 220, the electro-optical conversion layer 230 arranged between the first-type semiconductor layer 210 and the second-type semiconductor layer 220, the first electrode 240 electrically connected to the first-type semiconductor layer 210, and the second electrode 250 electrically connected to the second-type semiconductor layer 220.

The first electrode 240 and the second electrode 250 of the light-emitting device ED illustrated in FIG. 15 may be arranged to be oriented in different directions. The first electrode 240 may be arranged below the electro-optical conversion layer 230, and the second electrode 250 may be arranged above the electro-optical conversion layer 230. The second electrode 250 may be electrically connected to a common electrode pad CP via a common electrode CE.

Although it has been described that the light-emitting device ED emits light of a particular wavelength, the disclosure is not limited thereto. The light-emitting device ED may emit light of a plurality of different wavelengths.

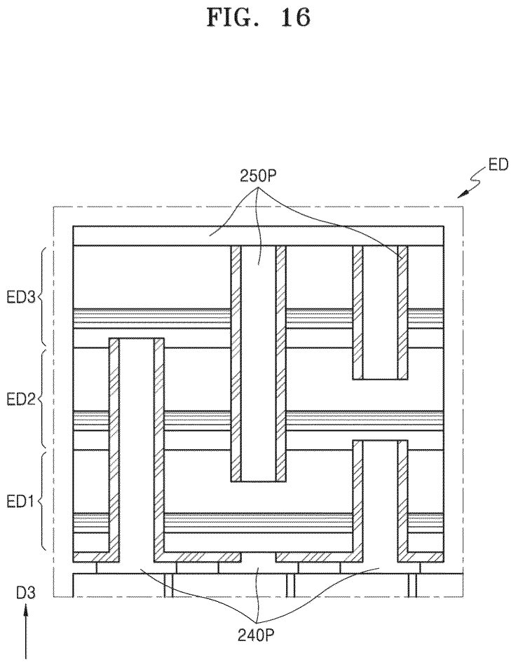

FIG. 16 is a diagram illustrating a light-emitting layer including the light-emitting device ED that emits light of a plurality of wavelengths, according to an embodiment of the disclosure.

Referring to FIG. 16, the light-emitting device ED may have a structure in which a first light-emitting element ED1 that emits light of a first wavelength, a second light-emitting element ED2 that emits light of a second wavelength different from the first wavelength, and a third light-emitting element ED3 that emits light of a third wavelength different from the first and second wavelengths, are stacked in the thickness direction of the display panel DP. For example, the first light-emitting element ED1 may emit red light, the second light-emitting element ED2 may emit green light, and the third light-emitting element ED3 may emit blue light.

The first to third light-emitting elements ED1, ED2, and ED3 may include first-type semiconductor layers, photoelectric conversion layers arranged on the first-type semiconductor layers, and second-type semiconductor layers arranged on the photoelectric conversion layers, respectively. The light-emitting device ED may include a first electrode pattern 240P connected to the first-type semiconductor layers P1, P2, and P3 of the respective first to third light-emitting elements ED1, ED2, and ED3, and a second electrode pattern 250P connected to the second-type semiconductor layers N1, N2, and N3 of the respective first to third light-emitting elements ED1, ED2, and ED3. Because a single light-emitting device ED includes a plurality of light-emitting elements ED1, ED2, and ED3, respectively having different wavelengths, the display panel DP may be miniaturized.

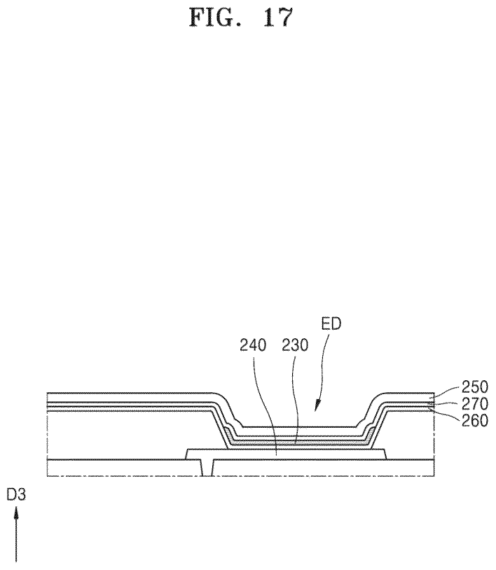

FIG. 17 is a diagram illustrating a light-emitting layer including an organic material-based light-emitting device, according to an embodiment of the disclosure. Referring to FIG. 17, the light-emitting device ED may be a light-emitting device that includes an organic material. An organic light-emitting diode may include the first electrode 240 arranged on an insulating layer, the second electrode 250 facing the first electrode 240, and the electro-optical conversion layer 230 arranged between the first electrode 240 and the second electrode 250. A first functional layer 260 may be arranged between the first electrode 240 and the electro-optical conversion layer 230, and a second functional layer 224 may be further arranged between the electro-optical conversion layer 230 and the second electrode 250.

The electro-optical conversion layer 230 may include a high-molecular or low-molecular organic material that emits light of a certain color. The first functional layer 260 may include a hole transport layer (HTL) and/or a hole injection layer (HIL). The second functional layer 224 may include an electron transport layer (ETL) and/or an electron injection layer (EIL).

Some embodiments of the disclosure may be implemented as a computer program or a computer program product including at least on computer-executable instruction such as a computer program executable by a computer.

A machine-readable storage medium may be provided in the form of a non-transitory storage medium. Here, the term ‘non-transitory storage medium’ refers to a tangible device and does not include a signal (e.g., an electromagnetic wave), and the term ‘non-transitory storage medium’ does not distinguish between a case where data is stored in a storage medium semi-permanently and a case where data is stored temporarily. For example, the ‘non-transitory storage medium’ may include a buffer in which data is temporarily stored.

According to an embodiment of the disclosure, methods according to various embodiments disclosed herein may be included in a computer program product and then provided. The computer program product may be traded as commodities between sellers and buyers. The computer program product may be distributed in the form of a machine-readable storage medium (e.g., a compact disc read-only memory (CD-ROM)), or may be distributed online (e.g., downloaded or uploaded) through an application store or directly between two user devices (e.g., smart phones). In a case of online distribution, at least a portion of the computer program product (e.g., a downloadable app) may be temporarily stored in a machine-readable storage medium such as a manufacturer's server, an application store's server, or a memory of a relay server.

According to an embodiment of the disclosure, a display apparatus may include a display panel DP including light-emitting devices ED arranged two-dimensionally, and light-sensing devices CD respectively corresponding to the light-emitting devices ED.

According to an embodiment of the disclosure, the display apparatus may include at least one processor PR configured to receive, from the display panel DP, a first sensing signal resulting from sensing by the light-sensing devices CD during a light emission period ET of the light-emitting devices ED, and a second sensing signal resulting from sensing by the light-sensing devices CD during a non-light emission period NET of the light-emitting devices ED, and control the display panel DP such that an image corresponding to at least one of the first sensing signal or the second sensing signal is displayed.

The processor PR may obtain, by using the first sensing signal and the second sensing signal, information about internal light, wherein the internal light is light that is emitted from the light-emitting devices ED, then travels only within the display panel DP, and is then incident on the light-sensing devices, and adjust luminance of the image in accordance with the information about the internal light.

The processor PR may obtain the information about the internal light by using a difference between the first sensing signal and the second sensing signal.

The information about the internal light may include information about a light emission state of the light-emitting devices ED.

The processor PR may obtain, by using the second sensing signal, information about external light, wherein the external light is light incident on the light-sensing devices CD from outside of the display panel DP, and display the image corresponding to the external light.

The external light may include light that is emitted from the display panel DP, is then reflected by an object that is external to the display panel DP, and then re-enters the display panel DP.

The information about the external light may include at least one of information about a user fingerprint, information about a user biometric information, information about a user touch, or information about an illuminance of an external environment.

Relative to a rear surface of the display panel, a rear surface of at least one of the light-emitting devices ED may be higher than an upper surface (or front surface) of at least one of the light-sensing devices CD.

The display panel may include a light-emitting layer DP_EL in which the light-emitting devices are arranged.

The display panel DP may include a light-sensing layer DP_DL arranged on a rear surface of the light-emitting layer DP_EL, wherein the light-sensing devices are arranged in the light-sensing layer DP_DL.

The display panel DP may include a circuit layer arranged on the rear surface of the light-emitting layer DP_EL, and including a light emission driving circuit configured to drive the light-emitting devices ED, and a sensing driving circuit configured to drive the light-sensing devices CD.

The light-sensing layer DP_DL and the circuit layer DP_CL may be arranged on a same layer.

A photoelectric conversion layer of at least one of the light-sensing devices CD and at least one of channel layers included in the circuit layer DP_CL may be arranged on a same layer.

At least one of the light-sensing devices CD may be a phototransistor.

At least one of the light-emitting devices ED may be an inorganic material-based light-emitting device.

A first light-emitting device among the light-emitting devices ED and a first light-sensing device among the light-sensing devices CD may correspond to each other.

A photoelectric conversion layer OEL of the first light-sensing device may include an area that does not overlap an electro-optical conversion layer 230 of the first light-sensing device in a thickness direction of the display panel DP.

The photoelectric conversion layer OEL of the first light-sensing device may further include an area that overlaps the electro-optical conversion layer 230 of the first light-sensing device in the thickness direction of the display panel DP.

The display panel DP may further include a light transmission member OT arranged between the first light-emitting device and the first light-sensing device in a direction perpendicular to the thickness direction of the display panel DP, and configured to transmit, to the first light-sensing device, light emitted from the first light-emitting device.

The light transmission member OT may include at least one of a reflection layer or a waveguide.

The light transmission member OT may be arranged on an upper surface (or front surface) of the light-emitting layer DP_EL.

The light transmission member OT may include a first light transmission member OT1 and a second light transmission member OT2 arranged spaced apart from each other with the photoelectric conversion layer OEL of the first light-sensing device therebetween, in the thickness direction of the display panel DP.

According to an embodiment of the disclosure, a method of operating a display apparatus may include receiving, from a display panel DP including light-emitting devices ED arranged two-dimensionally and light-sensing devices CD respectively corresponding to the light-emitting devices ED, a first sensing signal resulting from sensing by the light-sensing devices CD during a light emission period ET of the light-emitting devices ED, and a second sensing signal resulting from sensing by the light-sensing devices CD during a non-light emission period NET of the light-emitting devices ED.

The method of operating a display apparatus may include controlling the display panel DP such that an image corresponding to at least one of the first sensing signal or the second sensing signal is displayed.

Although embodiments of the disclosure have been described above in detail, the scope of the disclosure is not limited thereto, and various modifications and alterations by those of skill in the art using the basic concept of the disclosure defined in the following claims also fall within the scope of the disclosure.

What is claimed is:

1. A display apparatus comprising:
a display panel comprising:
light-emitting devices in a two-dimensional array; and
light-sensing devices respectively corresponding to the light-emitting devices;
memory storing at least one instruction; and
at least one processor,
wherein the at least one instruction, when executed by the at least one processor individually or collectively, causes the display apparatus to:
receive a first sensing signal from the light-sensing devices during a light emission period of the light-emitting devices,
receive a second sensing signal from the light-sensing devices during a non-light emission period of the light-emitting devices, and
control the display panel to display an image corresponding to at least one of the first sensing signal or the second sensing signal.

2. The display apparatus of claim 1, wherein the at least one instruction, when executed by the at least one processor individually or collectively, further causes the display apparatus to:
obtain, based on the first sensing signal and the second sensing signal, information about internal light that is emitted from the light-emitting devices, travels only within the display panel, and is incident on the light-sensing devices, and
adjust luminance of the image based on the information about the internal light.

3. The display apparatus of claim 2, wherein the at least one instruction, when executed by the at least one processor individually or collectively, further causes the display apparatus to obtain the information about the internal light based on a difference between the first sensing signal and the second sensing signal.

4. The display apparatus of claim 3, wherein the information about the internal light comprises information about a light emission state of the light-emitting devices.

5. The display apparatus of claim 1, wherein the at least one instruction, when executed by the at least one processor individually or collectively, further causes the display apparatus to:
obtain, based on the second sensing signal, information about external light incident on the light-sensing devices from outside of the display panel, and
display the image corresponding to the external light.

6. The display apparatus of claim 5, wherein the external light comprises light that is emitted from the display panel, is reflected by an object that is external to the display panel, and re-enters the display panel.

7. The display apparatus of claim 5, wherein the information about the external light comprises at least one of information about a fingerprint of a user, information about biometric information of the user, information about a touch of the user, or information about an illuminance of an external environment.

8. The display apparatus of claim 1, wherein a rear surface of at least one of the light-emitting devices is further than a front surface of at least one of the light-sensing devices from a rear surface of the display panel.

9. The display apparatus of claim 1, wherein the display panel further comprises:
a light-emitting layer comprising the light-emitting devices;
a light-sensing layer on a rear surface of the light-emitting layer, wherein the light-sensing layer comprises the light-sensing devices; and
a circuit layer on the rear surface of the light-emitting layer, the circuit layer comprising:
a light emission driving circuit configured to drive the light-emitting devices; and
a sensing driving circuit configured to drive the light-sensing devices.

10. The display apparatus of claim 9, wherein the light-sensing layer and the circuit layer are on a same layer.

11. The display apparatus of claim 10, wherein a photoelectric conversion layer of at least one of the light-sensing devices and at least one of channel layers in the circuit layer are on a same layer.

12. The display apparatus of claim 1, wherein at least one of the light-sensing devices is a phototransistor.

13. The display apparatus of claim 1, wherein at least one of the light-emitting devices is an inorganic material-based light-emitting device.

14. The display apparatus of claim 1, wherein a first light-emitting device among the light-emitting devices corresponds to a first light-sensing device among the light-sensing devices, and
wherein a photoelectric conversion layer of the first light-sensing device comprises an area that does not overlap an electro-optical conversion layer of the first light-emitting device in a thickness direction of the display panel.

15. The display apparatus of claim 14, wherein the photoelectric conversion layer of the first light-sensing device further comprises an area that overlaps the electro-optical conversion layer of the first light-emitting device in the thickness direction of the display panel.

16. The display apparatus of claim 14, wherein the display panel further comprises a light transmission member between the first light-emitting device and the first light-sensing device in a direction perpendicular to the thickness direction of the display panel, and
wherein the light transmission member is configured to transmit, to the first light-sensing device, light emitted from the first light-emitting device.

17. The display apparatus of claim 16, wherein the light transmission member comprises at least one of a reflection layer or a waveguide.

18. The display apparatus of claim 16, further comprising:
a light-emitting layer comprising the light-emitting devices;
wherein the light transmission member is on a front surface of the light-emitting layer.

19. The display apparatus of claim 16, wherein the light transmission member comprises a first light transmission member and a second light transmission member spaced apart with the photoelectric conversion layer of the first light-sensing device therebetween, in the thickness direction of the display panel.

20. A method of operating a display apparatus including a display panel that includes light-emitting devices in a two-dimensional array and light-sensing devices respectively corresponding to the light-emitting devices, the method comprising:
receiving a first sensing signal from the light-sensing devices during a light emission period of the light-emitting devices;
receiving a second sensing signal from the light-sensing devices during a non-light emission period of the light-emitting devices; and
controlling the display panel to display an image corresponding to at least one of the first sensing signal or the second sensing signal.
